(19) United States
(12) Patent Application Publication
(10) Pub. No.: US 2025/0220886 A1
(43) Pub. Date: Jul. 3, 2025

(54) SEMICONDUCTOR STRUCTURE AND METHOD FOR FORMING THE SAME

(71) Applicant: Winbond Electronics Corp., Taichung City (TW)

(72) Inventors: Tai-An HOU, Kaohsiung City (TW); Kazutaka MANABE, Taichung City (TW); Pei-Hsiu PENG, Kaohsiung City (TW)

(73) Assignee: Winbond Electronics Corp., Taichung City (TW)

(21) Appl. No.: 18/658,245

(22) Filed: May 8, 2024

(30) Foreign Application Priority Data
Jan. 3, 2024 (TW) 113100245

(51) Int. Cl. H10B 12/00

(52) U.S. Cl. CPC H10B 12/34; H10B 12/053

(57) ABSTRACT

A semiconductor structure and a method for forming the same are provided. The semiconductor structure includes a substrate, an isolation feature, and first and second word lines. The substrate has an array area and an adjacent dummy word line area. The isolation feature is disposed in the substrate in the array area and the dummy word line area to define an active region of the substrate. A first word line including first conductive structures is buried in the substrate in the dummy word line area and extends across the active region and the isolation feature. The second word line including a second conductive structure is buried in the substrate in the array area and extends across the active region and the isolation feature. A first top surface of each of the first conductive structures is below a second top surface of the second conductive structure.

### CROSS REFERENCE TO RELATED APPLICATIONS

This Application claims priority of Taiwan Patent Application No. 113100245, filed on Jan. 3, 2024, the entirety of which is incorporated by reference herein.

### BACKGROUND OF THE DISCLOSURE

### Field of the Disclosure

The present disclosure relates to a semiconductor structure and a method for forming the same and, in particular, to a dynamic random access memory structure and a method for forming the same.

### Description of the Related Art

Dynamic Random Access Memory (DRAM) devices are widely used in consumer electronic products. In order to increase element density in a DRAM device and improve its overall performance, existing technologies for fabricating DRAM devices continue to focus on scaling down the size of the elements. However, as element density continues to increase, certain challenges associated with it also arise. For example, the leakage current generated between adjacent bit lines still needs to be improved.

### BRIEF SUMMARY OF THE DISCLOSURE

An embodiment of the present disclosure provides a semiconductor structure which includes a substrate, an isolation feature, a first word line, and a second word line. The substrate has an array area and a dummy word line area adjacent to the array area. The isolation feature is disposed in the substrate in the array area and the dummy word line area to define an active region of the substrate. The first word line is buried in the substrate in the dummy word line area and extends across the active region and the isolation feature. The first word line includes first conductive structures. The second word line is buried in the substrate in the dummy word line area and extends across the active region and the isolation feature. The second word line includes a second conductive structure. A first top surface of each of the first conductive structures is below a second top surface of the second conductive structure.

An embodiment of the present disclosure provides a method for forming a semiconductor structure, which includes providing a substrate, wherein the substrate has an array area and a dummy word line area adjacent to the array area. The method further includes forming an isolation feature in the substrate to define an active region; forming a first word line in the substrate in the dummy word line area, wherein the first word line extends across the active region and the isolation feature, and wherein the first word line includes first conductive structures. The method further includes forming a second word line in the substrate in the array area, wherein the second word line extends across the active region and the isolation feature, wherein the second word line includes a second conductive structure, and wherein a first top surface of each of the first conductive structures is below a second top surface of the second conductive structure.

### BRIEF DESCRIPTION OF THE DRAWINGS

The present disclosure can be more fully understood by reading the subsequent detailed description and examples with references made to the accompanying drawings, wherein:

FIG. 1 is a schematic top view of a semiconductor structure in accordance with some embodiments of the disclosure;

FIG. 2 is a schematic partial enlarged view of FIG. 1, showing the layout of a semiconductor structure in accordance with some embodiments of the disclosure;

FIG. 3 is a schematic cross-sectional view taken along the line A-A′ of the semiconductor structure of FIG. 2 in accordance with some embodiments of the disclosure;

FIGS. 4, 5, and 6 are schematic cross-sectional views of intermediate stages of forming the semiconductor structure of FIG. 3 in accordance with some embodiments of the disclosure.

### DETAILED DESCRIPTION OF THE DISCLOSURE

The following description is made for the purpose of illustrating the general principles of the disclosure and should not be taken in a limiting sense. The scope of the disclosure is best determined by reference to the appended claims.

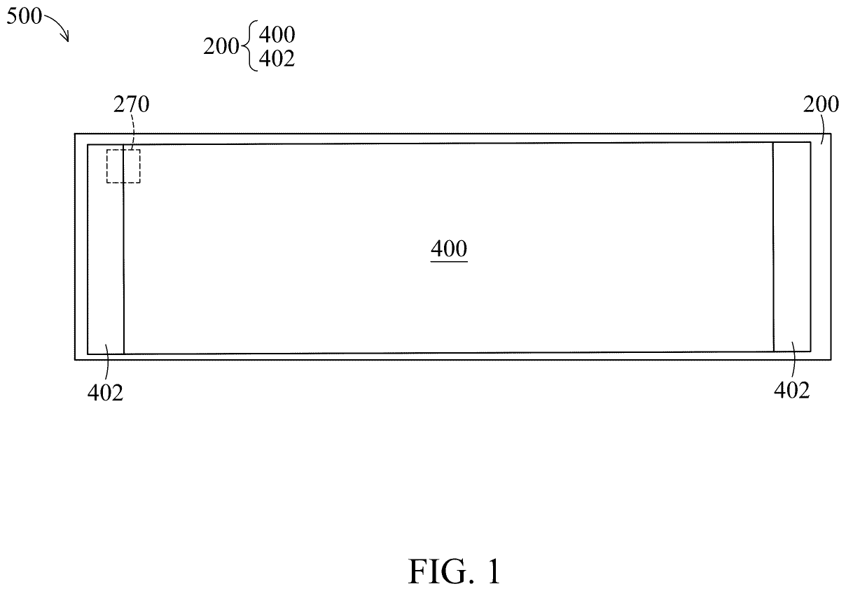

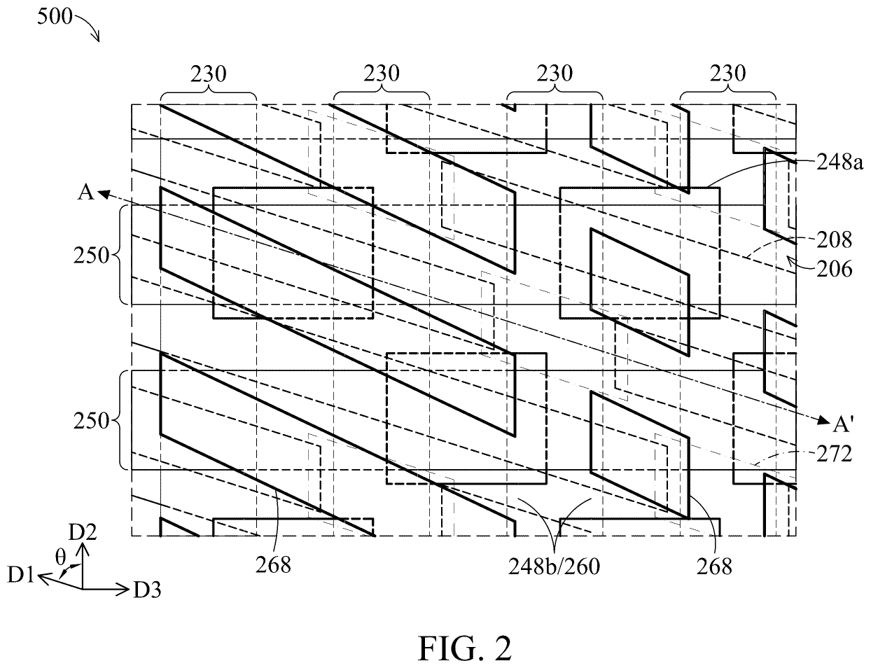

FIG. 1 is a schematic top view of a semiconductor structure 500 in accordance with some embodiments of the disclosure. FIG. 2 is a schematic partial enlarged view of an area 270 of FIG. 1, showing the layout of the semiconductor structure 500 in accordance with some embodiments of the disclosure. For illustration of the reference directions labeled in the figures, a direction D1 is defined as the channel extending direction, a direction D2 is defined as the gate extending direction (or the word line extending direction), and a direction D3 is defined as the bit line extending direction. The direction D2 is substantially perpendicular to the direction D3. The direction D1 and the direction D2 intersect at an acute angle θ.

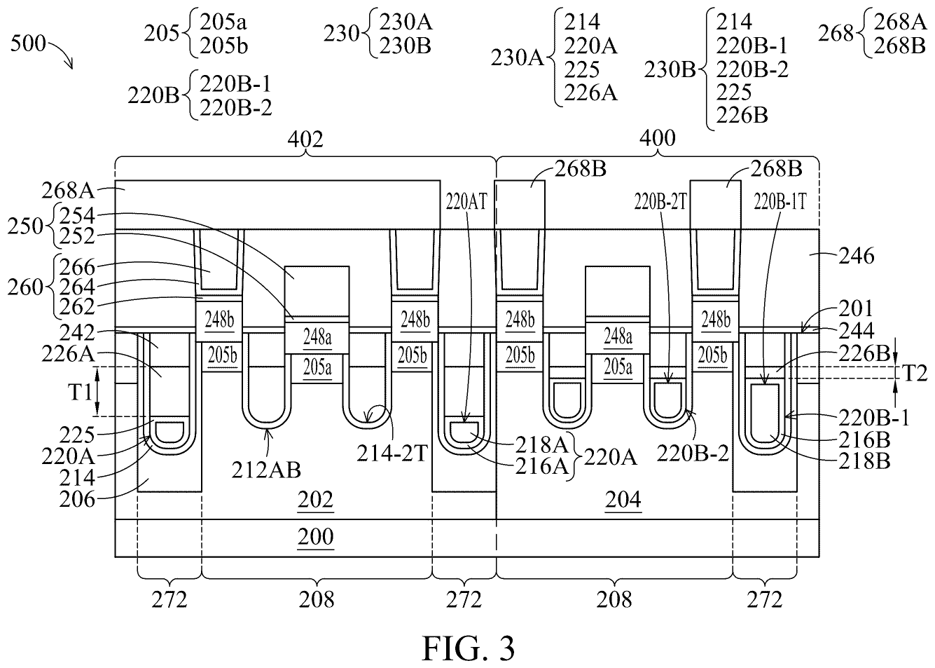

As shown in FIGS. 1 and 2, in some embodiments, the semiconductor structure 500 is a portion of a DRAM. The semiconductor structure 500 includes a substrate 200, an isolation feature 206, active regions 208, word lines 230, contact plugs 248a and 248b, bit lines 250, and storage capacitors 260. For illustration, FIGS. 1 and 2 only show some of the features for illustration. The remaining features can be illustrated in the schematic cross-section views of FIGS. 3 to 6. FIGS. 3 to 6 are taken along the line A-A′ of FIG. 2, which is substantially parallel to the direction D1.

As shown in FIGS. 1 and 2, the substrate 200 has an array area 400 and a dummy word line area 402 adjacent to the array area 400. The isolation feature 206 is formed in the substrate 200 in the array area 400 and the dummy word line area 402 to define a plurality of the active regions 208 in the substrate 200. The active regions 208 extend along the direction D1. In addition, the active regions 208Are spaced apart along the direction D1 and the direction D2, respectively. The adjacent active regions 208 on the same line along the direction D1 completely overlap each other and are separated from each other by the isolation features 206 of the cut-off region 272. In the direction D2, the adjacent cut-off regions 272 are misaligned or non-overlapping. The adjacent active regions 208 on the same line along the direction D2 partially overlap each other and are separated from each other by the isolation feature 206. In some embodiments, the size of the memory cells of the semiconductor structure 500 is 6F² (3F in length, 2F in width, F being the minimum feature size).

The word lines 230 are formed in the substrate 200 and extend along the direction D2. In the direction D3, the word lines 230 are arranged in a way of a pair of the adjacent word lines 230 corresponds to one active region 208. The bit lines 250 are formed over the substrate 200 and extend along the direction D3. The bit lines 250 are arranged corresponding to the active regions 208 in the direction D2. The storage capacitors 260 are formed above the substrate 200 and are located in regions between an adjacent pair of word lines 230 and an adjacent pair of bit lines 250.

The contact plugs 248a are located at the intersections of the bit lines 250 and the active region 208. When the bit line 250 is formed crossing the pair of the word lines 230 corresponding to the active region 208, the bit line 250 is electrically connected to a block of the active region 208 between the pair of word lines 230 through the contact plug 248a. The contact plugs 248b are located between an adjacent pair of the word lines 230 and an adjacent pair of the bit lines 250 and partially overlap the corresponding active regions 208. The storage capacitors 260 are electrically connected to end portions of the corresponding active regions 208 through the contact plugs 248b.

FIG. 3 is a schematic cross-sectional view taken along the line A-A′ of the semiconductor structure 500 of FIG. 2 in accordance with some embodiments of the disclosure. Referring to FIG. 3, the semiconductor structure 500 includes the substrate 200, the isolation feature 206, a first word line 230A, a second word line 230B, a first well region 202 and a second well region 204.

The first well region 202 is located in the substrate 200 in the dummy word line area 402. The second well region 204 is located in the substrate 200 in the array area 402. The first well region 202 and the second well region 204 have the same conductivity type and different doping concentrations. For example, the first well region 202 has a first doping concentration, the second well region 204 has a second doping concentration, and the first doping concentration is greater than the second doping concentration.

As shown in FIGS. 2 and 3, the isolation feature 206 is disposed in the substrate 200 to define the active region 208 of the substrate 200. The bottom surface of isolation feature 206 is located within the first well region 202 and the second well region 204. The isolation feature 206 may be a shallow trench isolation and formed of, for example, silicon oxide (SiO), silicon nitride (SiN), silicon oxynitride (SiON), and/or a combination thereof. In some embodiments, the isolation feature 206 is formed using a patterning process followed by deposition and planarization processes.

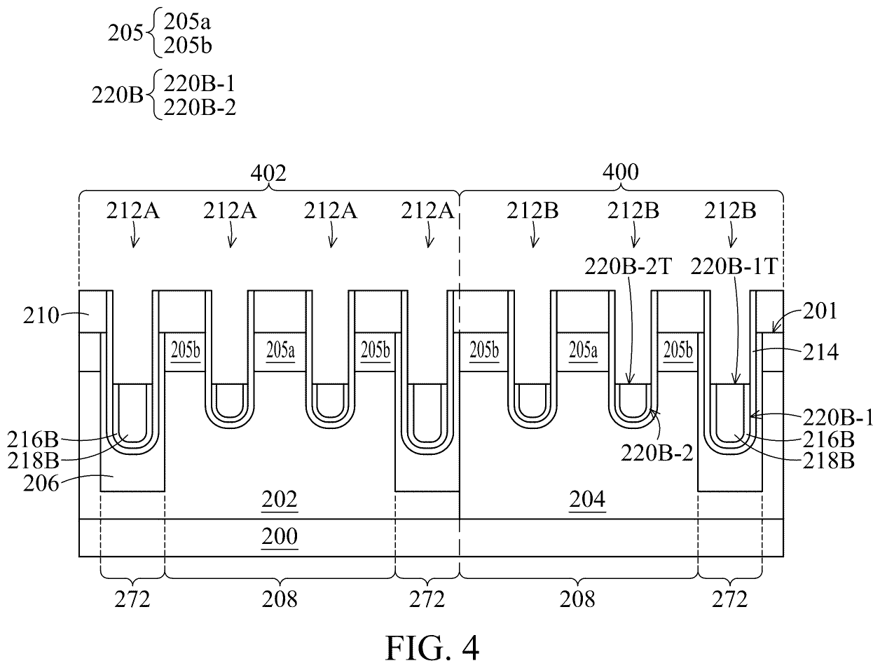

As shown in FIG. 3, the first word line 230A is buried in the first trench 212A (as shown in FIG. 4) of the substrate 200 in the dummy word line area 402 and extends across the active region 208 and isolation feature 206. Furthermore, the first word line 230A is disposed in the first well region 202. In some embodiments, the first word line 230A includes a gate dielectric layer 214, first conductive structures 220A disposed on the gate dielectric layer 214, and a work function adjustment structure 226A disposed on the first conductive structures 220A. The first word line 230A further includes a liner 225 disposed between the first conductive structure 220A and the work function adjustment structure 226A.

The gate dielectric layer 214 conformally covers the first trench 212A (as shown in FIG. 4). In some embodiments, the gate dielectric layer 214 is formed of, for example, silicon oxide, silicon nitride, silicon oxynitride and/or a high dielectric constant (k) dielectric material.

In some embodiments, the first conductive structures 220A of the first word line 230A are discontinuously arranged along the word line extending direction (the direction D2). In detail, the first conductive structure 220A of the first word line 230A is located in the first trench 212A in the isolation feature 206 in the cut-off region 272. In addition, there is no first conductive structure 220A in the first trench 212A in the active region 208 (there are only the gate dielectric layer 214 and the work function adjustment structure 226A of the first word line 230A but not the first conductive structure 220A in the first trench 212A in the active region 208). Moreover, the first conductive structure 220A covers the gate dielectric layer 214 in the first trench 212A in the isolation feature 206, but does not cover the gate dielectric layer 214 on the bottom surface 212AB of the first trench 212A in the active region 208. In some embodiments, the top surface 220AT of the first conductive structure 220A is level with the upper surface 214-2T of the gate dielectric layer 214 on the bottom surface 212AB of the first trench 212A in the active region 208.

In some embodiments, the first conductive structure 220A includes a liner 216A and a gate electrode layer 218A. The liner 216 conformally covers the first trench 212A in the substrate 200 (as shown in FIG. 4). In addition, the gate electrode layer 218A is disposed on the liner 216A and partially fills the first trench 212A. In some embodiments, the liner 216A includes tungsten nitride (WN) (the work function is about 4.6), titanium nitride (TiN) (the work function is about 4.7), or tantalum nitride (TaN) (the work function is about 4.5). The gate electrode layer 218A includes a metal such as tungsten (W) (the work function is about 4.52). In some embodiments, the material and forming method of the liner 225 covering the first conductive structure 220A may be similar to those of the liner 216A.

The work function adjustment structure 226A is in contact with the liner 225 in the first trench 212A in the isolation feature 206 in the cut-off region 272. In addition, the work function adjustment structure 226A is in contact with the upper surface 214-2T of the polar dielectric layer 214 on the bottom surface 212AB of the first trench 212A in the active region 208. The work function adjustment structure 226A is a conductive structure, which is made of different materials and has different structures from the first conductive structure 220A. In some embodiments, a work function of the work function adjustment structure 226A is less than a work function of the first conductive structure 220A and greater than a work function of the substrate 200 (e.g., the work function of the substrate 200 of silicon is about 3.9). The work function adjustment structure 226A is used to reduce the electric field generated in the overlapping region of the work function adjustment structure 226A with the drain doped region of the resulting semiconductor structure, thereby reducing gate induced drain leakage current (GIDL). Therefore, the channel leakage and the junction leakage from the drain doped region to the underlying substrate 200 can be further reduced. In some embodiments, the work function adjustment structure 226A may be a single-layer structure, which may include doped polysilicon, such as N-type doped polysilicon (the work function is about 4.05). The liner 216A, the gate electrode layer 218A and the work function adjustment structure 226A can be individually formed by chemical vapor deposition (CVD), physical vapor deposition (PVD), or atomic layer deposition (ALD).

As shown in FIG. 3, the second word line 230B is buried in the second trench 212B (as shown in FIG. 4) in the substrate 200 in the array area 400 and extends across the active region 208 and the isolation feature 206. Furthermore, the second word line 230B is disposed in the second well region 204. In some embodiments, the second word line 230B includes the gate dielectric layer 214, a second conductive structure 220B disposed on the gate dielectric layer 214, and a work function adjustment structure 226B disposed on the second conductive structure 220B. The second word line 230B further includes the liner 225 disposed between the second conductive structure 220B and the work function adjustment structure 226B.

In some embodiments, the second conductive structure 220B of the second word lines 230B is continuously arranged along the extending along the word line extending direction (the direction D2). A top surface 220B-1T of a first portion 220B-1 of the second conductive structure 220B in the cut-off region 272 is level with a top surface of 220B-2T of a second portion 220B-2 of the first conductive structure 220B in the active region 208. In some embodiments, the top surface 220AT of the first conductive structure 220A is located below the top surfaces 220B-1T, 220B-2T of the second conductive structure 220B. The second conductive structure 220B may include a liner 216B and a gate electrode layer 218B. The liner 216B conformally covers the second trench 212B in the substrate 200 (as shown in FIG. 4). The gate electrode layer 218B is disposed on the liner 216B and partially fills the second trench 212B. The liners 216A and 216B have the same material and formation method and are formed at the same time. Furthermore, the gate electrode layers 218A and 218B have the same material.

The work function adjustment structure 226B is in contact with the liner 225. In some embodiments, the work function adjustment structures 226A and 226B have the same material and formation method and are formed at the same time. Furthermore, a thickness T1 of the work function adjustment structure 226A may be greater than a thickness T2 of the work function adjustment structure 226B.

As shown in FIG. 3, the semiconductor structure 500 further includes a doped region 205. The doping region 205 includes a doping region (a source doping region) 205a and a doping region (a drain doping region) 205b. The doping regions 205a and 205b are disposed in the active region 208 and adjacent to the first word line 230A and second word line 230B. Furthermore, the first conductive structure 220A and the first portion 220B-1 of the second conductive structure 220B in the isolation feature 206 in the cut-off region 272 are located below the doped region 205 and do not overlap the doped region 205.

The semiconductor structure 500 further includes a capping layer 242. The capping layer 242 is disposed on the first word line 230A and the second word line 230B and fills the first trench 212A and the second trench 212B (as shown in FIG. 4). The capping layer 242 may be formed of a dielectric material, such as silicon nitride or silicon oxide. In some embodiments, the capping layer 242 is formed by a deposition process and a subsequent planarization process. The deposition process includes a deposition process with good step coverage or high conformity, such as atomic layer deposition (ALD). In some embodiments, the planarization process includes chemical mechanical polishing (CMP) and/or an etching back process.

The semiconductor structure 500 further includes a capping layer 244 formed on a top surface 201 of the substrate 200 and covering the word line 230A. In some embodiments, the capping layer 244 is formed of oxide, such as silicon oxide. The capping layer 244 is formed using a deposition process (e.g., CVD, ALD, and/or a combination thereof).

The semiconductor structure 500 further includes an interlayer dielectric layer 246 disposed on the substrate 200. The interlayer dielectric layer 246 includes, for example, silicon oxide, silicon nitride, silicon oxynitride, phosphosilicate glass (PSG), borophosphosilicate glass (BPSG), other suitable low-k dielectric materials, or a combination thereof. In this embodiment, the interlayer dielectric layer 246 includes silicon nitride.

The contact plugs 248a and 248b of the semiconductor structure 500 are disposed on the substrate 200, pass through the interlayer dielectric layer 246 and the capping layer 244. In addition, the contact plugs 248a and 248b are electrically connected to the doping regions 205a and 205b, respectively. In some embodiments, the contact plugs 248a and 248b are formed of a conductive material. The contact plugs 248a and 248b are formed in openings (not shown) of interlayer dielectric layer 246 and capping layer 244 using a deposition process and subsequent removal process.

As shown in FIGS. 2 and 3, the bit line 250 is formed over the substrate 200 and in the interlayer dielectric layer 246. In addition, the bit line 250 is disposed on the contact plugs 248a and is electrically connected to the doped region 205a through the contact plugs 248a. In some embodiments, the bit line 250 includes a barrier layer 252 formed on the contact plug 248a and a conductive layer 254 formed on the barrier layer 252. The barrier layer 252 is formed of titanium (Ti), tantalum (Ta), titanium nitride (TiN), and/or tantalum nitride (TaN). The conductive layer 254 is formed of tungsten (W), aluminum (Al), and/or copper (Cu). In some embodiments, the bit line 250 is formed suing a deposition process and a subsequent removal process.

The storage capacitor 260 of the semiconductor structure 500 is disposed above the substrate 200 and the contact plug 248b, and is electrically connected to the doped region 205b through the contact plug 248b. In some embodiments, the storage capacitor 260 includes a first electrode 262, a dielectric 264 and a second electrode 266 formed on the contact plug 248b in sequence. The first electrode 262 and the second electrode 266 may include a conductive material. In addition, the dielectric 264 may include a high dielectric constant (k) dielectric material. In some embodiments, the storage capacitor 260 is formed using, for example, a deposition process and a subsequent removal process.

As shown in FIGS. 2 and 3, the semiconductor structure 500 further includes a conductive line 268 on the storage capacitor 260. The conductive line 268 includes a conductive line 268A disposed within the dummy word line area 402 and a conductive line 268B disposed within the array area 400. In some embodiments, the different storage capacitors 260 arranged in the dummy word line area 402 along the direction D1 (the channel extending direction) are connected to the same conductive line 268A. Furthermore, the different storage capacitors 260 arranged in the array area 400 along the direction D1 (the channel extending direction) are connected to different conductive lines 268B.

The method for forming the semiconductor structure 500 will be described below. Please refer to FIG. 4, a substrate 200 is provided. Next, multiple ion implantation processes are performed to implant a dopant of a first conductivity type into the substrate 200 in the dummy word line area 402 and the adjacent array area 400, and implant a dopant of a second conductivity type opposite to the first conductivity type into the substrate 200 in the dummy word line area 402. The multiple ion implantation are performed to form the first well region 202 in the substrate 200 in the dummy word line area 402 and the second well region 204 in the substrate 200 in the array area 400. Furthermore, a dopant of the second conductivity type opposite to the first conductivity type is implanted into the substrate 200 to form the doped region 205 on the first well region 202 and the second well region 204.

Next, a patterning process is performed to form trenches (not shown) in the substrate 200 to define the formation locations of the isolation features 206. Next, a deposition process is performed to deposit dielectric materials in the trenches, and then a planarization process is performed to form the isolation features 206 in the substrate 200. The isolation features 206 extend downwardly from the top surface 201 of the substrate 200 to define the active regions 208 of the substrate 200. Bottom surfaces of the isolation features 206 are located within the first well region 202 and the second well region 204.

Next, a deposition process and a lithography process and an etching process are performed sequentially to form the hard mask patterns 210 on the top surface 201 of the substrate 200 to define the first trenches 212A and the second trenches 212B for forming the first word line 230A and the second word line 230B. In some embodiments, the hard mask patterns 210 extend along the direction D2 and are spaced apart along the direction D3, exposing portions of the substrate 200 and portions of the isolation features 206.

Next, an etching process (e.g., dry etching) using the hard mask patterns 210 as etching masks is performed on the exposed substrate 200 and the isolation feature 206 to form the first trenches 212A in the first well region 202 within the dummy word line area 402 and the second trenches 212B in the second well region 204 within the array area 400. Since the etch rate of the substrate 200 (such as silicon) and the isolation feature 206 (such as silicon oxide) are different, the depths of the first trench 212A and the second trench 212B in the isolation feature 206 are greater than the depths of the first trench 212A and the second trench 212B in the active region 208.

Next, multiple deposition processes are performed to conformally form the gate dielectric layer 214 in the first trench 212A and the second trench 212B. Next, a liner is conformally formed (not shown) to cover the gate dielectric layer 214. Next, a gate electrode layer (not shown) is deposited in the first trench 212A and the second trench 212B to cover the gate dielectric layer 214 and the liner. In addition, the gate electrode layer fills the first trench 212A and the second trench 212B. Next, an etching back process (e.g., dry etching) is performed to remove a portion of the liner and a portion of the gate electrode layer on the substrate 200 and in the first trench 212A and the second trench 212B, so that the upper portion of the trench 212 is exposed again, so as to form the second conductive structure 220B in the lower portion of the second trench 212B, which includes the liner 216B and the gate electrode layer 218B. In some embodiments, a top surface 220B-1T of a first portion 220B-1 of the second conductive structure 220B in the isolation feature 206 is level with a top surface 220B-2T of a second portion 220B-2 of the second conductive structure 220B in the active region 208.

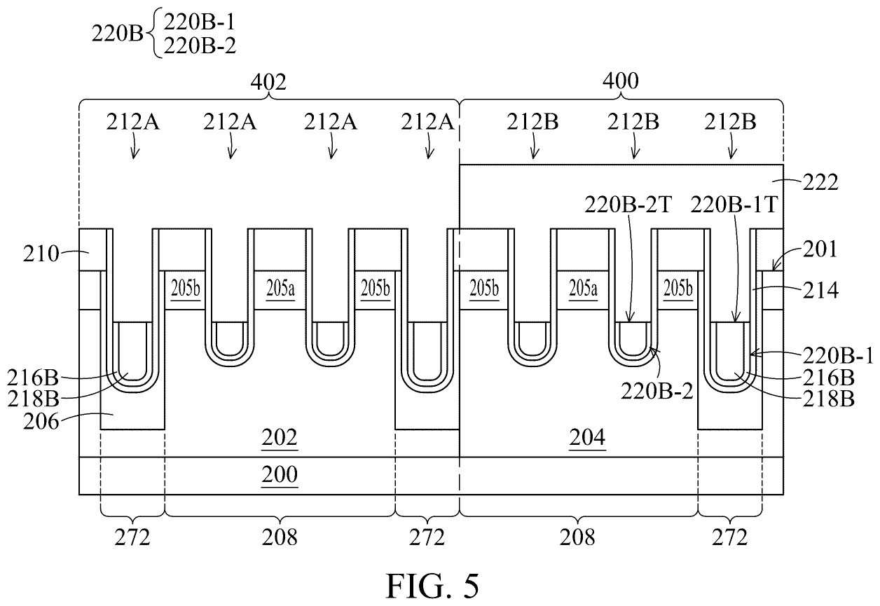

Next, as shown in FIG. 5, the patterned mask 222 is formed to cover the second trench 212B in the array area 400 and exposes the first trench 212A in the dummy word line area 402.

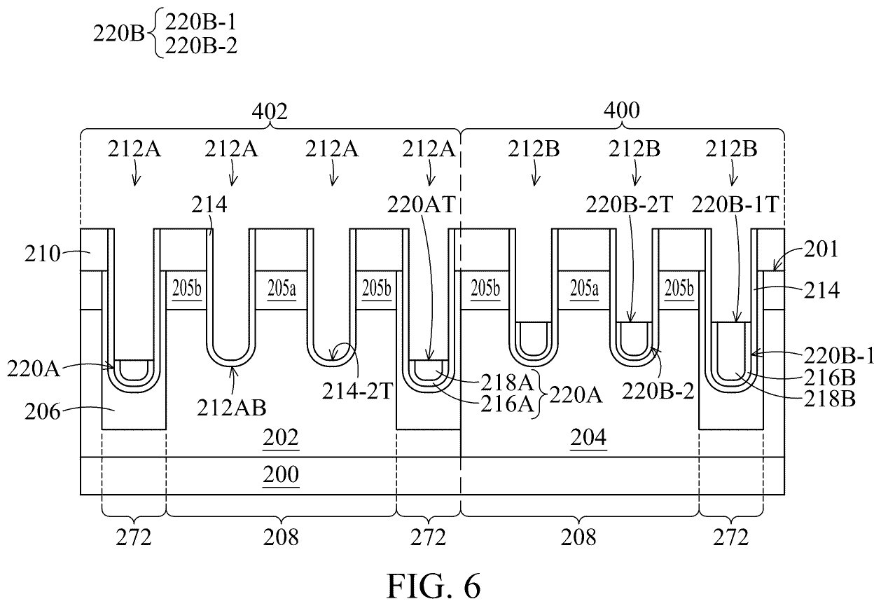

Next, as shown in FIG. 6, an etching back process is performed to remove a portion of the liner 216B and a portion of the gate electrode layer 218B in the first trench 212A to form the first conductive structure 220A. The etching back process completely removes the liner 216B and the gate electrode layer 218B in the first trench 212A in the active region 208 until the gate dielectric layer 214 on the bottom surface 212AB of the first trench 212A in the active region 208 is exposed. After performing the etching back process, the first conductive structure 220A is formed in the isolation feature 206 in the cut-off region 272 in the dummy word line area 402. The first conductive structure 220A includes the liner 216A and a gate electrode layer 218A. A top surface 220AT of the first conductive structure 220A is level with an upper surface 214-2T of the gate dielectric layer 214 on the bottom surface 212AB of the first trench 212A in the active region 208. After forming the first conductive structure 220A, the patterned mask 222 is removed.

Next, as shown in FIG. 3, a liner material (for example, the same material as the liner 216A) is deposited to conformally cover the first conductive structure 220A and the second conductive structure 220B. Next, another etching back process is performed to remove a portion of the conductive material in the first trench 212A and the second trench 212B, so that the upper portions of the first trench 212A and the second trench 212B and a portion of the gate dielectric layer 214 are exposed to form the liner 225.

Next, as shown in FIG. 3, a conductive material (not shown) is deposited to cover the liner 225 and fill the first trench 212A and the second trench 212B. Next, another etching back process is performed to remove a portion of the conductive material in the first trench 212A and the second trench 212B, so that the upper portions of the first trench 212A and the second trench 212B and a portion of the gate dielectric layer 214 are exposed to form the work function adjustment structures 226A and 226B. After performing the aforementioned processes, the first word line 230A is formed in the substrate 200 in the dummy word line area 402, and the second word line 230B is formed in the substrate 200 in the array area 400. The first word line 230A and the second word line 230B extend across active region 208 and isolation feature 206. The top surface 220AT of the first conductive structure 220A of the first word line 230A is located below the top surfaces 220B-1T and 220B-2T of the second conductive structure 220B.

Next, as shown in FIG. 3, a deposition process and a subsequent planarization process are performed to form the capping layer 242 on the first trench 212A and the second trench 212B, and fill the upper portions of the first trench 212A and the second trench 212B. The top surface of the capping layer 242 is level with the top surface 201 of the substrate 200.

Next, as shown in FIG. 3, deposition processes are performed to form the cap layer 244 and the interlayer dielectric layer 246 over the substrate 200. Next, a patterning process, a deposition process, and a removal process are performed in sequence to form the contact plugs 248a and 248b in the openings (not shown) of the capping layer 244 and the interlayer dielectric layer 246.

Next, as shown in FIG. 3, a deposition process and subsequent removal process (including a planarization process (e.g., CMP), an etching back process, or a combination thereof) are performed to form the bit line 250, the storage capacitor 260 and the conductive line 268. After performing the aforementioned processes, the semiconductor structure 500 is formed. In addition, additional components, such as interconnect structures, peripheral circuits, or other suitable components, may be formed on the semiconductor structure 500 to fabricate a semiconductor memory device.

Embodiments provide a semiconductor structure and a method of forming the same. In some embodiments, the well region in the dummy word line area has a heavier doping concentration than the well region in the array area of the semiconductor structure. In addition, the first conductive structures of the first word line in the dummy word line area are discontinuously arranged along the word line extending direction to increase the work function of the first word line in the dummy word line area. The threshold voltage (VT) of the first word line is accordingly increased. In the normal operation, all the first word lines can be kept in the OFF state and are not easily switched to the ON state even if the semiconductor structure suffers the process variations or electronic noise. Compared with the conventional DRAM in which the word line in the dummy word line area is simultaneously connected to different storage capacitors arranged along the channel line extending direction in the array area, the semiconductor structure in accordance with some embodiments of the disclosure can avoid leakage paths generated between the adjacent bit lines that impacts the performance of the DRAM cell in the array area.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate having an array area and a dummy word line area adjacent to the array area;
an isolation feature disposed in the substrate in the array area and the dummy word line area to define an active region of the substrate;
a first word line buried in the substrate in the dummy word line area and extending across the active region and the isolation feature, wherein the first word line comprises first conductive structures; and
a second word line buried in the substrate in the array area and extending across the active region and the isolation feature, wherein the second word line comprises a second conductive structure, wherein a first top surface of each of the first conductive structures is below a second top surface of the second conductive structure.

2. The semiconductor structure as claimed in claim 1, wherein the first conductive structures are discontinuously arranged along a word line extending direction.

3. The semiconductor structure as claimed in claim 1, wherein the first word line is formed in a first trench of the substrate in the dummy word line area, and no first conductive structure is in the first trench in the active region.

4. The semiconductor structure as claimed in claim 3, wherein the first conductive structures are disposed in the first trench in the isolation feature.

5. The semiconductor structure as claimed in claim 3, wherein the first word line further comprises:
a gate dielectric layer conformally covering the first trench, wherein the first conductive structures are disposed on the gate dielectric layer, and wherein the gate dielectric layer on a bottom surface of the first trench in the active region is not covered by the first conductive structures; and
a work function adjustment structure disposed on the first conductive structures.

6. The semiconductor structure as claimed in claim 5, wherein the first conductive structures cover the gate dielectric layer in the first trench in the isolation feature.

7. The semiconductor structure as claimed in claim 5, wherein the first top surface of each of the first conductive structures is level with an upper surface of the gate dielectric layer on the bottom surface of the first trench in the active region.

8. The semiconductor structure as claimed in claim 5, wherein the work function adjustment structure is in contact with the upper surface of the gate dielectric layer on the bottom surface of the first trench in the active region.

9. The semiconductor structure as claimed in claim 5, wherein each of the first conductive structures comprises:
a liner conformally covering the gate dielectric layer; and
a gate electrode layer disposed on the liner and partially filling the first trench.

10. The semiconductor structure as claimed in claim 3, further comprising:
a first well region located in the substrate within the dummy word line area; and
a second well region located in the substrate within the array area, wherein the first well region and the second well region have the same conductivity type and different doping concentrations.

11. The semiconductor structure as claimed in claim 10, wherein the first well region has a first doping concentration, the second well region has a second doping concentration, and the first doping concentration is greater than the second doping concentration.

12. The semiconductor structure as claimed in claim 10, wherein the first word line is disposed in the first well region.

13. A method for forming a semiconductor structure, comprising:
providing a substrate, wherein the substrate has an array area and a dummy word line area adjacent to the array area;
forming an isolation feature in the substrate to define an active region;
forming a first word line in the substrate in the dummy word line area, wherein the first word line extends across the active region and the isolation feature, and wherein the first word line comprises first conductive structures; and
forming a second word line in the substrate in the array area, wherein the second word line extends across the active region and the isolation feature, wherein the second word line comprises a second conductive structure, and wherein a first top surface of each of the first conductive structures is below a second top surface of the second conductive structure.

14. The method for forming a semiconductor structure as claimed in claim 13, further comprising:
implanting a first dopant into the substrate in the dummy word line area and the array area before forming the first word line and the second word line; and
implanting a second dopant into the substrate in the dummy word line area to form a first well region in the substrate in the dummy word line area and a second well region in the substrate in the array area, wherein the second dopant has the same conductivity type as the first dopant.

15. The method for forming a semiconductor structure as claimed in claim 13, further comprising:
forming a first trench in the first well region within the dummy word line area, and forming a second trench in the second well region within the array area;
conformally forming a gate dielectric layer and a first liner covering the gate dielectric layer in the first trench and the second trench;
forming a gate electrode layer covering the first liner in the first trench and the second trench, wherein the gate electrode layer fills the first trench and the second trench; and
performing an etching back process to remove a portion of the first liner and a portion of the gate electrode layer in the first trench and the second trench to form the second conductive structure.

16. The method for forming a semiconductor structure as claimed in claim 15, further comprising:
forming a patterned mask covering the second trench to expose the first trench after forming the second conductive structure; and
removing a portion of the first liner and a portion of the gate electrode layer in the first trench to form the first conductive structures.

17. The method for forming a semiconductor structure as claimed in claim 16, wherein removing the portion of the first liner and the portion of the gate electrode layer in the first trench comprises completely removing the first liner and the gate electrode layer in the first trench in the active region.

18. The method for forming a semiconductor structure as claimed in claim 15, wherein removing the portion of the first liner and the portion of the gate electrode layer in the first trench until the gate dielectric layer on a bottom surface of the first trench in the active region is exposed.

19. The method for forming a semiconductor structure as claimed in claim 15, wherein forming the first word line and the second word line further comprises:
forming a second liner in the first trench and the second trench, wherein the second liner covers the first conductive structure and the second conductive structure; and
forming work function adjustment structures in the first trench and the second trench, wherein the work function adjustment structures cover the second liner and fill the first trench and the second trench.

20. The method for forming a semiconductor structure as claimed in claim 15, further comprising:
forming a capping layer on the first word line and the second word line, wherein the capping layer fills the first trench and the second trench;
forming bit lines on the substrate, wherein the bit lines are electrically connected to drain doped regions of the active region;
forming storage capacitors on the substrate, wherein the storage capacitors are electrically connected to source doping regions of the active region; and
forming conductive lines on the storage capacitors, wherein the storage capacitors arranged in the dummy word line area and along a channel extending direction are connected to the same conductive line, and wherein the storage capacitors arranged in the array area and along the channel extending direction are connected to different conductive lines.
